(19) United States
(12) Patent Application Publication
(10) Pub. No.: US 2026/0165214 A1
(43) Pub. Date: Jun. 11, 2026

(54) INTEGRATED CIRCUIT (IC) STRUCTURE AND FLOORPLAN THEREOF

(71) Applicant: ALCHIP TECHNOLOGIES, LIMITED, GRAND CAYMAN (KY)

(72) Inventors: WEN-HSI LIN, TAIPEI CITY (TW); KAI-TING HO, TAIPEI CITY (TW); EREZ SHAIZAF, NIR CHEN (IL)

(21) Appl. No.: 19/377,099

(22) Filed: Nov. 3, 2025

Related U.S. Application Data
(60) Provisional application No. 63/729,588, filed on Dec. 9, 2024.

(51) Int. Cl. H10W 90/22

(52) U.S. Cl. CPC H10W 90/22

(57) ABSTRACT

The present disclosure provides an integrated circuit (IC) structure. The IC structure includes a carrier and a plurality of groups arranged in an array on the carrier. Each of the plurality of groups includes an electronic component and a plurality of memories electrically connected with the electronic component through the carrier. The IC structure further includes a first hole defined by the carrier and configured to accommodate a first fixing element to hold the IC structure to another surface. The hole is disposed between two rows of the array.

### CROSS REFERENCE TO RELATED APPLICATION

This application claims the benefit of U.S. provisional application No. 63/729,588, filed Dec. 9, 2024, the content of which is incorporated herein by reference in its entirety.

### BACKGROUND

### 1. Technical Field

The present disclosure relates to an integrated circuit (IC) structure and a floorplan of the IC structure.

### 2. Description of the Related Art

IC structures combine various dies such as processors, memory units, interfaces, and power regulators, all integrated onto a single wafer. Existing floorplans are complex and costly, which limits competitive pricing. Therefore, efficient cell layout strategies that optimize IC performance and reliability within fixed floorplan constraints, while also improving yield, are important.

### SUMMARY

In some arrangements, an integrated circuit (IC) structure includes a carrier and a plurality of groups arranged in an array on the carrier. Each of the plurality of groups includes an electronic component and a plurality of memories electrically connected with the electronic component through the carrier. The IC structure further includes a first hole defined by the carrier and configured to accommodate a first fixing element to hold the IC structure to another surface. The hole is disposed between two rows of the array.

In some arrangements, an IC structure includes a carrier and a plurality of groups arranged in an array on the carrier. Each of the plurality of groups includes a plurality of electronic components forming a square pattern and a plurality of memories disposed around the plurality of electronic components and electrically connected with the carrier.

In some arrangements, an IC structure includes a wafer having a first surface, a first electronic component disposed over the first surface of the wafer, and a second electronic component disposed over the first surface of the wafer and aligning with the first electronic component along a first direction. The IC structure further includes a plurality of memories disposed over the first surface of the wafer, and disposed between the first electronic component and the second electronic component along the first direction. The plurality of memories are electrically connected to the first electronic component and the second electronic component through the wafer. The plurality of memories are aligned with one another along a second direction.

### BRIEF DESCRIPTION OF THE DRAWINGS

Aspects of some arrangements of the present disclosure are best understood from the following detailed description when read with the accompanying figures. It should be noted that various structures may not be drawn to scale, and dimensions of the various structures may be arbitrarily increased or reduced for clarity of discussion.

FIG. 1A illustrates a top view of an IC structure in accordance with some arrangements of the present disclosure.

FIG. 1B illustrates a cross-sectional view of an IC structure in accordance with some arrangements of the present disclosure.

FIG. 1C illustrates a cross-sectional view of an IC structure in accordance with some arrangements of the present disclosure.

FIG. 1D illustrates a cross-sectional view of an IC structure in accordance with some arrangements of the present disclosure.

FIG. 1E illustrates a cross-sectional view of an IC structure in accordance with some arrangements of the present disclosure.

FIG. 1F illustrates a cross-sectional view of an IC structure in accordance with some arrangements of the present disclosure.

FIG. 2 illustrates a top view of an IC structure in accordance with some arrangements of the present disclosure.

FIG. 3 illustrates a top view of an IC structure in accordance with some arrangements of the present disclosure.

FIG. 4 illustrates a top view of an IC structure in accordance with some arrangements of the present disclosure.

FIG. 5 illustrates a top view of an IC structure in accordance with some arrangements of the present disclosure.

FIG. 6 illustrates a top view of an IC structure in accordance with some arrangements of the present disclosure.

FIG. 7 illustrates a top view of an IC structure in accordance with some arrangements of the present disclosure.

FIG. 8 illustrates a top view of an IC structure in accordance with some arrangements of the present disclosure.

FIG. 9 illustrates a top view of an IC structure in accordance with some arrangements of the present disclosure.

FIG. 10 illustrates a top view of an IC structure in accordance with some arrangements of the present disclosure.

FIG. 11 illustrates a top view of an IC structure in accordance with some arrangements of the present disclosure.

### DETAILED DESCRIPTION

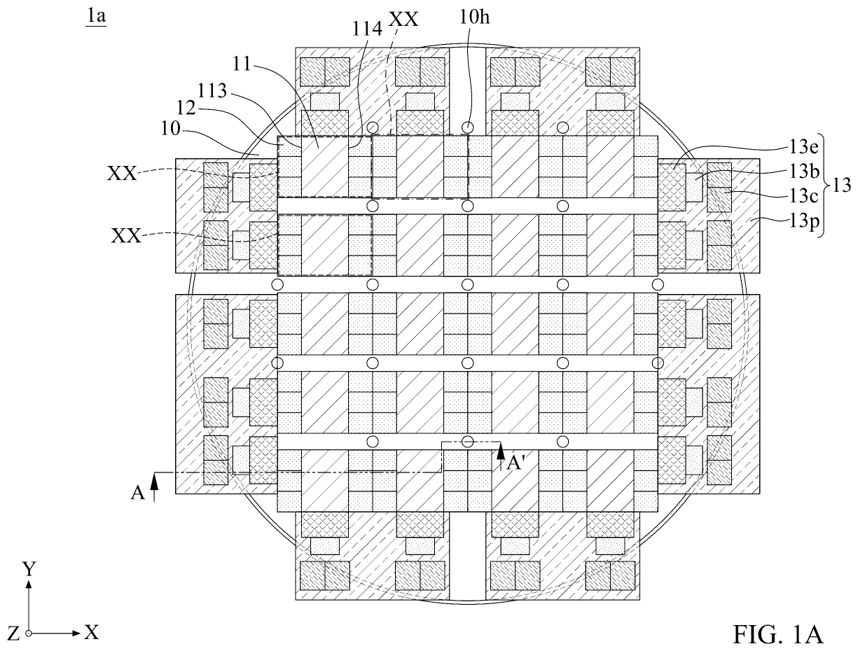

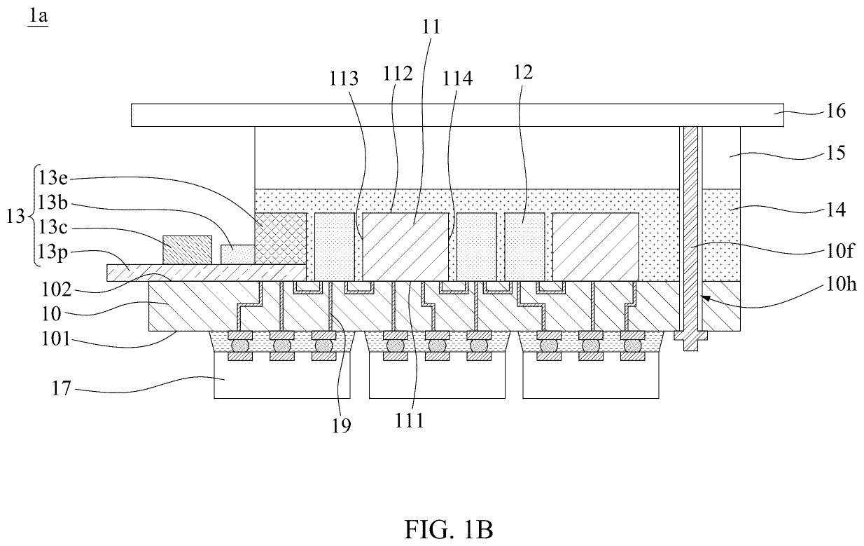

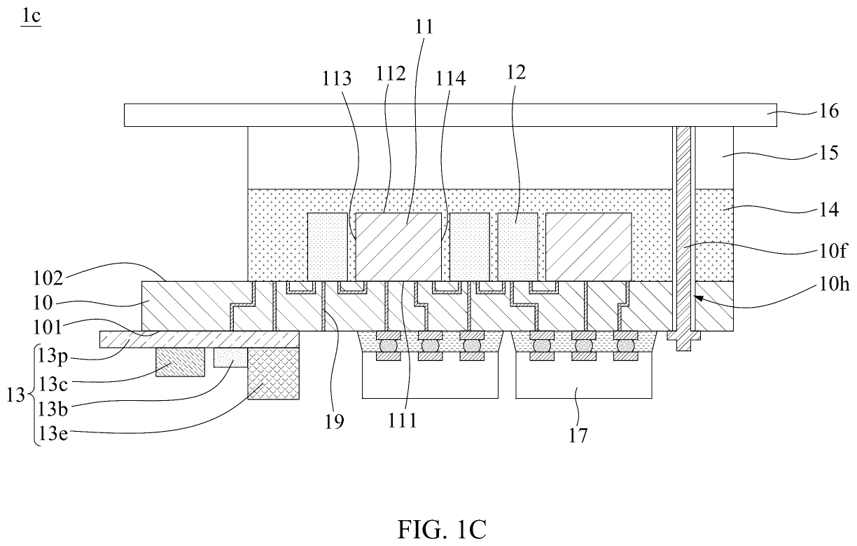

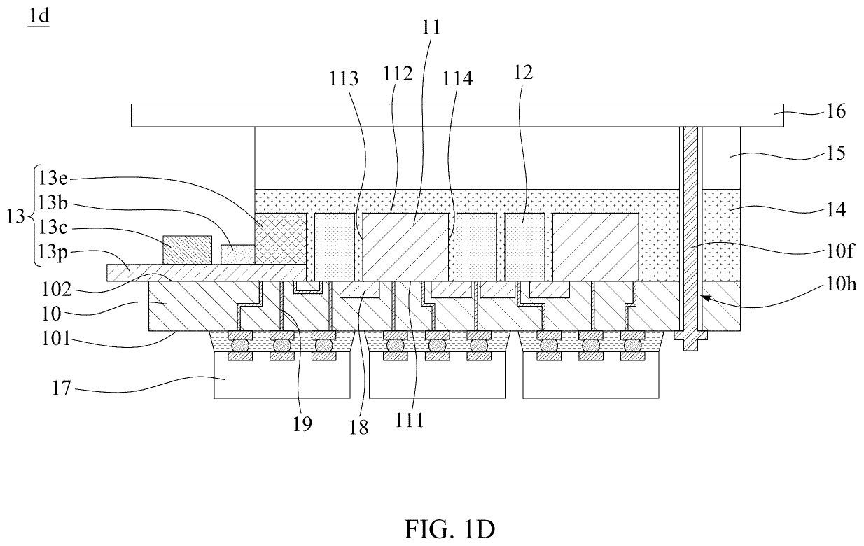

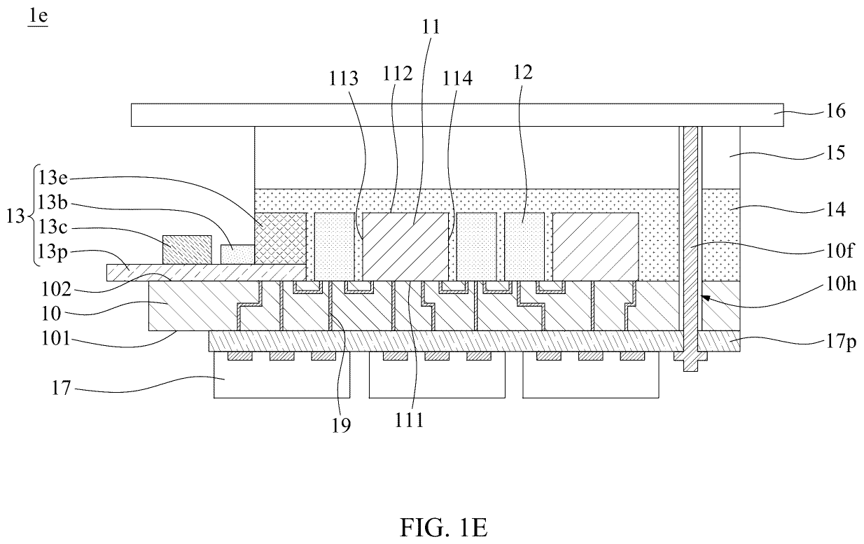

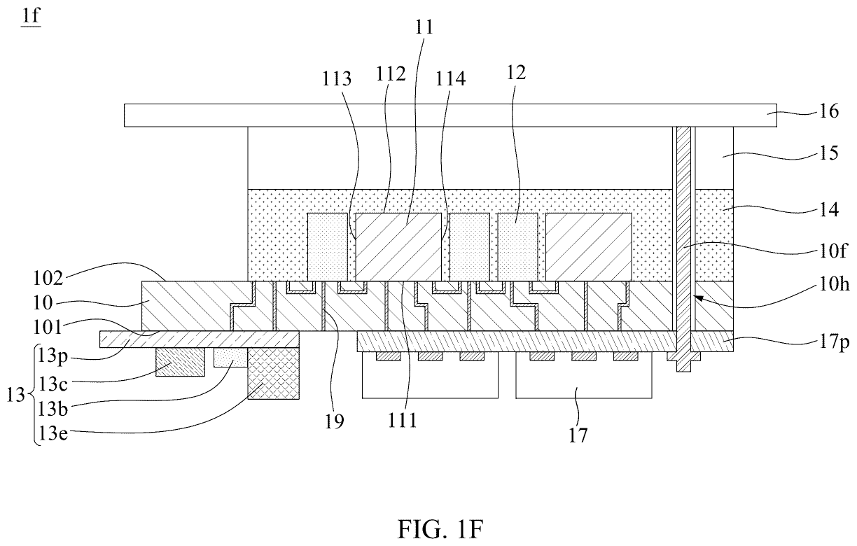

FIG. 1A illustrates a top view of an IC structure 1a in accordance with some arrangements of the present disclosure. FIG. 1B illustrates a cross-sectional view of the IC structure 1a cut through the line AA′ in FIG. 1A. The IC structure 1a may include a system on wafer (SoW). In some arrangements, the IC structure 1a may be used in applications requiring rapid access to extensive datasets, including high-performance computing, graphics processing, and artificial intelligence workloads.

The IC structure 1a may include a carrier 10, one or more electronic components 11, one or more memories 12, one or more connectors 13, and an encapsulant 14, a heat dissipating element 15, a frame 16, and one or more voltage regulators 17. The encapsulant 14, the heat dissipating element 15, the frame 16, and the voltage regulators 17 are omitted from FIG. 1A for clarity.

The carrier 10 may include a monolithic substrate or a platform. In some arrangements, the carrier 10 may include, for example, silicon, silicon carbide, gallium nitride, gallium arsenide, aluminum nitride, or other suitable materials. In some arrangements, the carrier 10 may include a monolithic wafer or a panel. For example, the carrier 10 may be circular, rectangular, or square.

The carrier 10 may include an interconnection structure or a circuit structure 19. The circuit structure 19 may include a redistribution layer (RDL), a circuit layer, conductive pillars, conductive pads, conductive traces, conductive vias, conductive wires, or other conductive elements. The circuit structure 19 may provide electrical connections for the components connected with the carrier 10.

The carrier 10 may include a surface 101 and a surface 102 opposite to the surface 101. The carrier 10 may include one or more conductive pads in proximity to, adjacent to, or embedded in and exposed by the surface 101 and/or the surface 102. The carrier 10 may include a solder resist on the surface 101 and/or the surface 102 to fully expose or expose at least a portion of the conductive pads for electrical connections.

The electronic components 11 may be disposed over the surface 102 of the carrier 10. The electronic components 11 may be electrically connected through the circuit structure 19 in the carrier 10, and the electrical connections may be attained by way of solder bonding, Cu-to-Cu bonding, wire bonding, or hybrid bonding. The electronic components 11 may be manufactured using a different process and subsequently mounted onto the carrier 10.

The electronic components 11 may be arranged in rows and columns. The electronic components 11 may be arranged along the X axis and the Y axis, as shown in FIG. 1A. The X axis may be referred to as the first direction, and the Y axis may be referred to as the second direction, or vice versa. The first direction may be substantially perpendicular to the second direction. The electronic components 11 may be arranged along an X-Y plane. The electronic components 11 may be arranged in an array, a grid, or an ordered series or arrangement. The electronic components 11 may have a square lattice arrangement.

The electronic components 11 may each include an integrated circuit (IC), a chip, or a die that includes a semiconductor substrate, one or more integrated circuit devices and one or more overlying interconnection structures therein. For example, the electronic components 11 may each include a controller, a processor, a central processing unit (CPU), a microprocessor unit (MPU), a graphics processing unit (GPU), a microcontroller unit (MCU), a field-programmable gate array (FPGA), a system on chip (SOC), an application specific integrated circuit (ASIC), or another type of IC. The electronic components 11 may be capable of initiating memory access operations using any of the memories 12 on the carrier 10.

The electronic components 11 may each include a surface 111 facing the carrier 10, a surface 112 opposite to the surface 111, a surface 113 extending between the surface 111 and the surface 112, and a surface 114 opposite to the surface 113, as shown in FIG. 1B. The surface 111 may be an active surface, a front surface, or a front side. The surface 112 may be a backside surface or a backside. The surfaces 113 and 114 may be sidewalls or lateral surfaces.

The memories 12 may be disposed over the surface 102 of the carrier 10. The memories 12 may be electrically connected through the circuit structure 19 in the carrier 10, and the electrical connections may be attained by way of solder bonding, Cu-to-Cu bonding, wire bonding, or hybrid bonding. The memories 12 may be manufactured using a different process and subsequently mounted onto the carrier 10.

The memories 12 may be electrically connected to the electronic components 11 through the carrier 10. The memories 12 may communicate with the electronic components 11 indirectly via the carrier 10, which serves as an intermediary platform facilitating signal transmission and data exchange between the two. The memories 12 may not directly communicate with the electronic components 11.

The memories 12 may be arranged in rows and columns. The memories 12 may be arranged along the X axis and the Y axis, as shown in FIG. 1A. The memories 12 may be arranged along an X-Y plane. The memories 12 may be arranged in an array, a grid, or an ordered series or arrangement. The memories 12 may have a square lattice arrangement.

The memories 12 may be disposed next to the electronic components 11. For example, the memories 12 and the electronic components 11 may align along the X axis. For example, the memories 12 and the electronic components 11 may overlap along the X axis. For example, the memories 12 and the electronic components 11 may alternatively be arranged along the X axis.

In some arrangements, one or more of the memories 12 may be disposed between two adjacent ones of the electronic components 11. For example, six memories of the memories 12 may be overlapped with two adjacent ones of the electronic components 11 along the X axis. The six memories of the memories 12 may be arranged in pairs in a row, forming a total of three rows. The six memories of the memories 12 may be arranged with three in a column, forming a total of two columns.

The memories 12 may be arranged along the electronic components 11. For example, the memories 12 may be arranged along the electronic components 11 in a systematic manner. For example, three memories 12 may be positioned along the surface 113 of the electronic component 11, while additional three memories 12 may be arranged along the surface 114 of the electronic component 11. This configuration allows for efficient use of space and facilitates optimal connectivity between the memories and the electronic components.

In some arrangements, the memories 12 may be or include a memory stack, such as a stack composed of multiple memory dies. This memory stack can be implemented as 3D-stacked memory, examples of which include high bandwidth memory (HBM) stacks, hybrid memory cubes (HMC), or similar advanced memory architectures that integrate several memory dies vertically to enhance performance and density. In some arrangements, the memories 12 may function as a high-speed, high-bandwidth memory resource that is closely coupled to the electronic components 11. This close coupling enables the electronic components 11 to efficiently read and write large volumes of data in parallel, thereby significantly improving data throughput and reducing latency.

In some arrangements, one or more of the memories 12 may be undesignated or shared memories that more than one of the electronic components 11 can access. This shared memory configuration optimizes space and memory access efficiency of the IC structure 1a, thereby enabling faster communication between the electronic components 11 to enhance overall system performance and data bandwidth.

In some arrangements, a single electronic component of the electronic components 11 and six memories of the memories 12 may be collectively referred to as a block or a group XX, as denoted by the dotted box. Multiple groups XX may be arranged in a row, or along the X axis. Multiple groups XX may be arranged in a column, or along the Y axis. Multiple groups XX may be arranged in an array, a grid, or an ordered series or arrangement. This hierarchical organization facilitates efficient data management and processing across the entire IC structure 1a.

The connectors 13 may be disposed over the periphery of the surface 102 of the carrier 10. The connectors 13 may be disposed on at least four sides of the carrier 10. The connectors 13 may be electrically connected through the circuit structure 19 in the carrier 10, and the electrical connections may be attained by way of solder bonding, Cu-to-Cu bonding, wire bonding, or hybrid bonding. The connectors 13 and the electronic components 11 may be disposed on the same side of the carrier 10, as shown in FIG. 1B, to simplify vias and through-hole connections, potentially decreasing parasitic inductance/capacitance and improving signal integrity.

The connectors 13 may be configured to provide external connections, enabling communication and power transfer between the IC structure 1a and external devices or systems. For instance, the connecting element 13c can establish electrical pathways that link the IC structure 1a to peripheral components, circuit boards, or other modules within an electronic assembly.

The connectors 13 may each include several components, including a printed circuit board (PCB) 13p, one or more network chips 13e, one or more electrical contacts 13b, and one or more connecting elements 13c. The PCB 13p may facilitate signal routing and mechanical support. The network chips 13e may handle data processing and communication functions within the connector 13, such as signal conditioning, protocol handling, or network interfacing.

In some arrangements, the electrical contacts 13b may include solder balls or solder bumps, such as controlled collapse chip connection (C4) bumps, a ball grid array (BGA) or a land grid array (LGA). In some arrangements, the connecting elements 13c may include conductive pillars, solder balls, conductive wires, board-to-board connectors, connectors suitable for Hot Bar soldering techniques, or combinations thereof. Additionally, other feasible connector types may be employed depending on the specific application requirements, manufacturing processes, and performance criteria.

It should be noted that although 20 electronic components, 120 memories, and 8 connectors are illustrated in FIG. 1A as an example, the scope is not limited to these specific quantities. In various arrangements, the number, relative positioning, absolute location, and orientation of the components may be selected or adjusted according to the specific design requirements or functional objectives.

As illustrated in FIG. 1B, the encapsulant 14 may be disposed over the surface 102 of the carrier 10. The encapsulant 14 may cover, surround, or encapsulate the electronic components 11 and the memories 12. The encapsulant 14 may cover, surround, or encapsulate the surface 112, the surface 113, and the surface 114 of the electronic component 11. The encapsulant 14 may separate the memory 12 from other components, such as the electronic component 11 adjacent to the memory 12 or another memory 12. The encapsulant 14 may separate the electronic component 11 from the six associated memories 12. The encapsulant 14 may cover, surround, or encapsulate the network chips 13e of the connectors 13. The encapsulant 14 may expose or uncover at least a part of the connectors 13.

The encapsulant 14 may include an epoxy resin with fillers, a molding compound (e.g., an epoxy molding compound or another type of molding compound), a polyimide, a phenolic compound or material, a material with a silicone dispersed therein, or a combination thereof.

The heat dissipating element 15 may be disposed over the encapsulant 14. In some arrangements, the heat dissipating element 15 may be connected to a surface of the encapsulant 14 through an adhesive layer, such as a heat dissipating gel. In some arrangements, in a direction substantially perpendicular to the surface 101 and/or the surface 102 of the carrier 10 (such as along the Z axis), the electronic component 11 and the heat dissipating element 15 may be at least partially overlapped to facilitate heat dissipation for the electronic component 11.

In some arrangements, in a direction substantially perpendicular to the surface 101 and/or the surface 102 of the carrier 10 (such as along the Z axis), the memory 12 and the heat dissipating element 15 may be at least partially overlapped to facilitate heat dissipation for the memory 12.

The heat dissipating element 15 may include a relatively high thermal conductivity. For example, the heat dissipating element 15 may include copper (Cu), aluminum (Al), graphite, ceramics, etc. The heat dissipating element 15 may include a block, a pipe, a sink, a fin, or other shapes.

The carrier 10, the encapsulant 14, and the heat dissipating element 15 may together define a hole 10h. From the top view in FIG. 1A, multiple holes 10h may be arranged in a row, or along the X axis. Multiple holes 10h may be arranged in a column, or along the Y axis. Multiple holes 10h may be arranged in an array, a grid, or an ordered series or arrangement. The holes 10h and the groups XX may be arranged along different rows. For example, the rows of the holes 10h and the rows of the groups may be alternately arranged along the Y axis.

The hole 10h may penetrate or extend through the carrier 10, the encapsulant 14, and the heat dissipating element 15. The hole 10h may be a continuous passage in the carrier 10, the encapsulant 14, and the heat dissipating element 15. A fixing element 10f may be disposed in the hole 10h. The hole 10h may be configured to accommodate the fixing element 10f.

The frame 16 may be disposed over the heat dissipating element 15. The frame 16 may be a bracket or a rest. The frame 16 may be configured to provide structural support for the IC structure 1a. The fixing element 10f may secure the carrier 10, the encapsulant 14, and the heat dissipating element 15 to the frame 16. The frame 16 and the fixing element 10f may be configured to hold or reinforce the IC structure 1a attached to another surface.

For example, the frame 16 and the fixing element 10f may be or include a mechanical or magnetic means to resist or arrest the movement of the IC structure 1a. The mechanical or magnetic means may prevent unintended separation of the IC structure 1a. For example, the frame 16 may have a thread that corresponds to the fixing element 10f, which may be a screw. In some other arrangements, the mechanical or magnetic means may include a pin, a post, a spring, a plugger, a buffer, a snap, a clip, a contour, etc.

The voltage regulators 17 may be disposed over the surface 101 of the carrier 10. The voltage regulators 17 may be electrically connected through the circuit structure 19 in the carrier 10, and the electrical connections may be attained by way of solder bonding, Cu-to-Cu bonding, wire bonding, or hybrid bonding.

The voltage regulators 17 may each include a linear regulator (configured to maintain a constant output voltage) or a switching regulator (configured to generate an output voltage that is higher or lower than the input voltage). In some arrangements, the voltage regulators 17 may each include a step-down (buck) converter, a step-up (boost) converter, an analog-to-digital converter, a digital-to-analog converter, an AC-DC converter, a DC-DC converter, other types of converters, or a combination thereof.

In some arrangements, the voltage regulators 17 may each include a power management integrated circuit (PMIC) (not shown). The voltage regulators 17 may each be configured to provide different types of power control to different parts of the IC structure 1a. For example, the voltage regulators 17 may each be configured to provide regulated power to the electronic components 11 and the memories 12. For example, the voltage regulators 17 may each be configured to provide different output voltages to the electronic components 11 and the memories 12.

It should be noted that the positions and number of the voltage regulators 17 in the IC structure 1a are not intended to limit the present disclosure. For example, the number of voltage regulators 17 in the IC structure 1a may vary depending on design requirements.

In a comparative arrangement, the memory may be placed on the electronic component and directly connected to it. As semiconductor process technologies advance differently for each component, heterogeneous integration becomes a challenge. In addition, a defect anywhere can ruin the entire IC structure, resulting in lower yields.

According to some arrangements of the present disclosure, using a carrier to connect the memory and the electronic component allows integration of components made with different processes without compromising the functionality. Each component can be tested and binned separately before assembly. Defective components can be discarded without scrapping the entire IC structure. Furthermore, the indirect communication pathway helps ensure proper electrical isolation and improves thermal management. Overall, the reliability and performance of the IC structure can be improved.

FIG. 1C illustrates a cross-sectional view of an IC structure 1c in accordance with some arrangements of the present disclosure. In some arrangements, the IC structure 1a cut through the line AA′ in FIG. 1A may have a cross-sectional view as shown in FIG. 1C. The IC structure 1c shown in FIG. 1C is similar to the IC structure 1a shown in FIG. 1B except that the connectors 13 shown in FIG. 1C are disposed over the periphery of the surface 101 of the carrier 10.

Referring to FIG. 1C, the connectors 13 and the electronic components 11 are respectively disposed on surfaces 101 and 102 of the carrier 10 to reduce electromagnetic interference (EMI) and crosstalk between high-speed signals and connector contacts. In addition, the connectors on the opposite side do not obstruct airflow or heat dissipation and allow easy access for cable connections during assembly and testing without disturbing the chip side.

FIG. 1D illustrates a cross-sectional view of an IC structure 1d in accordance with some arrangements of the present disclosure. In some arrangements, the IC structure 1a cut through the line AA′ in FIG. 1A may have a cross-sectional view as shown in FIG. 1D. The IC structure 1d shown in FIG. 1D is similar to the IC structure 1a shown in FIG. 1A except that the memories 12 shown in FIG. 1D communicate with the electronic components 11 via interposers 18.

Referring to FIG. 1D, the interposers 18 may be disposed or embedded in the carrier 10. The interposers 18 may be at least partially exposed from the carrier 10. The interposers 18 may be at least partially disposed on the surface 102 of the carrier 10.

The interposers 18 may have a relatively higher density or a relatively finer pitch wiring layer than the carrier 10. The interposers 18 may help reduce signal delay, noise, and crosstalk. In addition, the interposers 18 may be configured to mix and match different memory capacities and types with the same electronic component, allowing for greater flexibility in the production workflow and enabling the integration of components that require specialized optimization techniques before assembly.

FIG. 1E illustrates a cross-sectional view of an IC structure 1e in accordance with some arrangements of the present disclosure. In some arrangements, the IC structure 1a cut through the line AA′ in FIG. 1A may have a cross-sectional view as shown in FIG. 1E. The IC structure 1e shown in FIG. 1E is similar to the IC structure 1a shown in FIG. 1B except that the voltage regulators 17 are connected to the carrier 10 through a printed circuit board (PCB) 17p. The fixing element 10f may penetrate or extend through the PCB 17p. The fixing element 10f may secure the PCB 17p to the frame 16. In some arrangements, the PCB 17p may include copper traces and pads designed to enable the voltage regulators 17 to connect to the carrier 10 with varying circuit densities and accommodate different electrical requirements.

FIG. 1F illustrates a cross-sectional view of an IC structure 1f in accordance with some arrangements of the present disclosure. In some arrangements, the IC structure 1a cut through the line AA′ in FIG. 1A may have a cross-sectional view as shown in FIG. 1F. The IC structure 1f shown in FIG. 1F is similar to the IC structure 1c shown in FIG. 1C except that the voltage regulators 17 are connected to the carrier 10 through the PCB 17p. The number and the size of the PCB 17p can be adjusted according to the different electrical requirements.

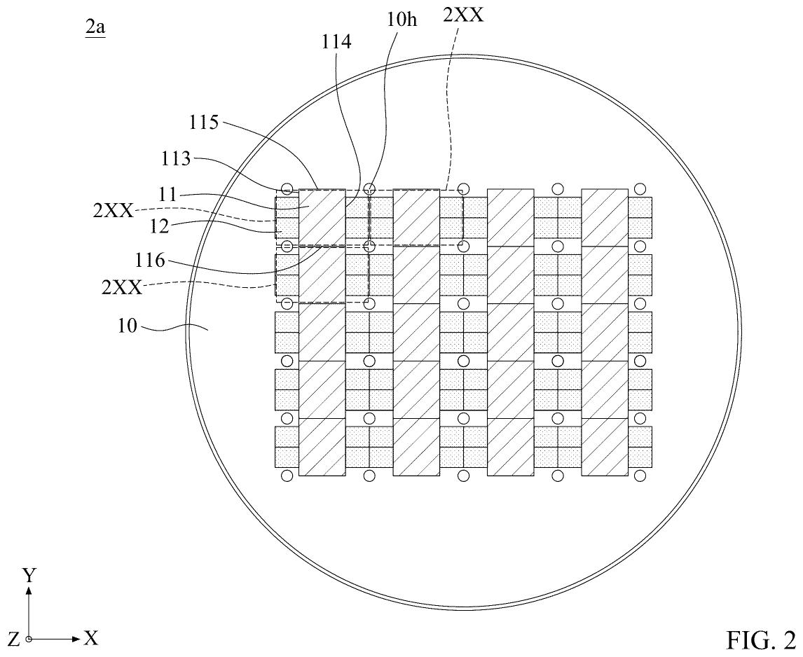

FIG. 2 illustrates a cross-sectional view of an IC structure 2a in accordance with some arrangements of the present disclosure. The IC structure 2a shown in FIG. 2 is similar to the IC structure 1a shown in FIG. 1A except that the connectors 13 are omitted from FIG. 2 for clarity, and the following differences apply.

Referring to FIG. 2, two memories 12 may be positioned along the surface 113 of the electronic component 11, while an additional two memories 12 may be arranged along the surface 114 of the electronic component 11. In some arrangements, a single electronic component of the electronic components 11 and four memories of the memories 12 may be collectively referred to as a block or a group 2XX.

The electronic components 11 may be arranged adjacent to one another or positioned in close proximity along the Y axis, allowing for a compact and efficient spatial configuration.

For example, the distance between two adjacent electronic components 11 along the Y axis may be less than the distance between two adjacent electronic components 11 along the X axis. For example, the electronic components 11 may each include a surface 115 extending between the surface 113 and the surface 114, and a surface 116 opposite to the surface 115. In some arrangements, the surface 116 of one of the electronic components 11 may be directly adjacent to or near touching the surface 115 of another one of the electronic components 11 through the encapsulant 14. In some arrangements, the holes 10h and the electronic components 11 may overlap along the X axis. The holes 10h and the electronic components 11 may be aligned along the X axis.

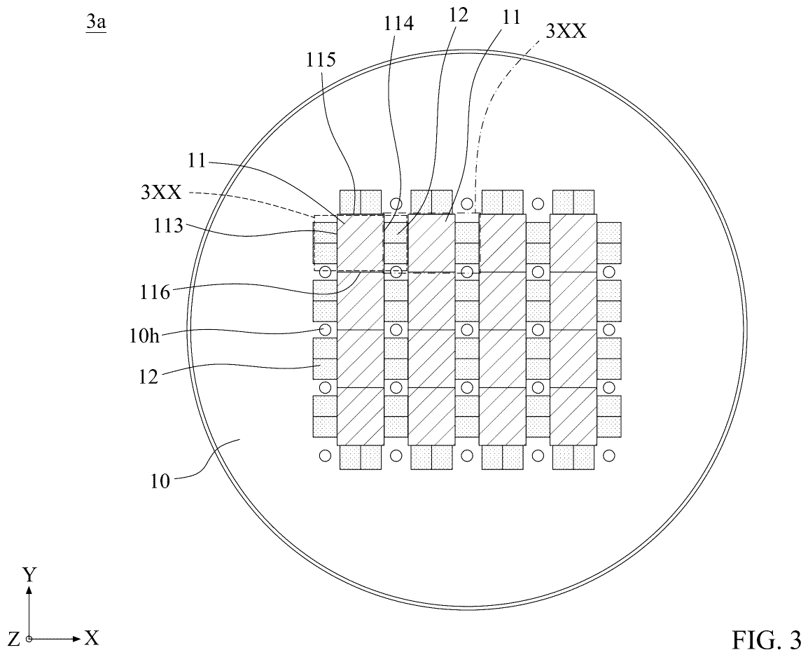

FIG. 3 illustrates a cross-sectional view of an IC structure 3a in accordance with some arrangements of the present disclosure. The IC structure 3a shown in FIG. 3 is similar to the IC structure 2a shown in FIG. 2, except for the following differences.

Referring to FIG. 3, in some arrangements, a single electronic component of the electronic components 11 and four memories of the memories 12 may be collectively referred to as a block or a group 3XX, in which two memories 12 may be positioned along the surface 113 of the electronic component 11, and an additional two memories 12 may be arranged along the surface 114 of the electronic component 11.

The adjacent ones of the electronic components 11 may share the same two memories 12. For example, two memories of the memories 12 located between two adjacent ones of the electronic components 11 along the X axis may be shared by both of these neighboring electronic components 11. For example, two memories of the memories 12 may be shared by two adjacent groups 3XX along the X axis.

The outermost or peripheral ones of the electronic components 11 may communicate with or connect to more memories 12. For example, the electronic components 11 located at the corners and along the edges of the array in the IC structure 3a can interface with up to six memories 12 positioned closely around them. In contrast, the electronic components 11 situated more centrally within the array typically communicate with four memories 12 surrounding them. This configuration allows for optimized memory access and efficient data transfer, particularly at the boundaries where additional connections help maintain performance and reduce latency.

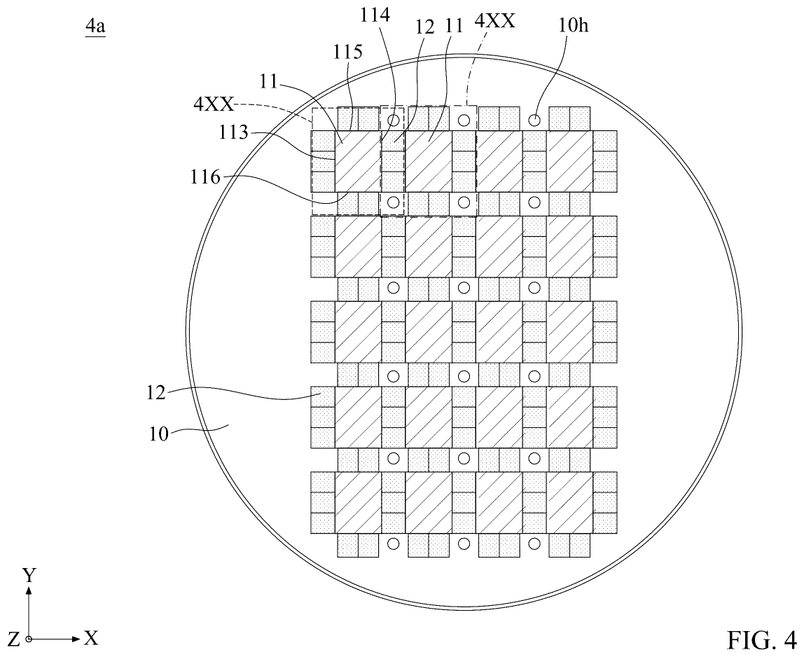

FIG. 4 illustrates a cross-sectional view of an IC structure 4a in accordance with some arrangements of the present disclosure. The IC structure 4a shown in FIG. 4 is similar to the IC structure 1a in FIG. 1A except that the connectors 13 are omitted from FIG. 4 for clarity, and the following differences apply.

Referring to FIG. 4, in some arrangements, a single electronic component of the electronic components 11 and ten memories of the memories 12 may be collectively referred to as a block or a group 4XX, in which three memories 12 may be positioned along the surface 113 of electronic component 11, three along the surface 114, and two each along the surfaces 115 and 116.

The adjacent ones of the electronic components 11 may share the same memories 12. For example, three memories of the memories 12 located between two adjacent ones of the electronic components 11 along the X axis may be shared by both of these two adjacent electronic components 11. For example, three memories of the memories 12 may be shared by two adjacent groups 4XX along the X axis.

In some arrangements, the holes 10h and some of the memories 12 may overlap or align along the X axis. In some arrangements, the holes 10h and some of the memories 12 may overlap or align along the Y axis.

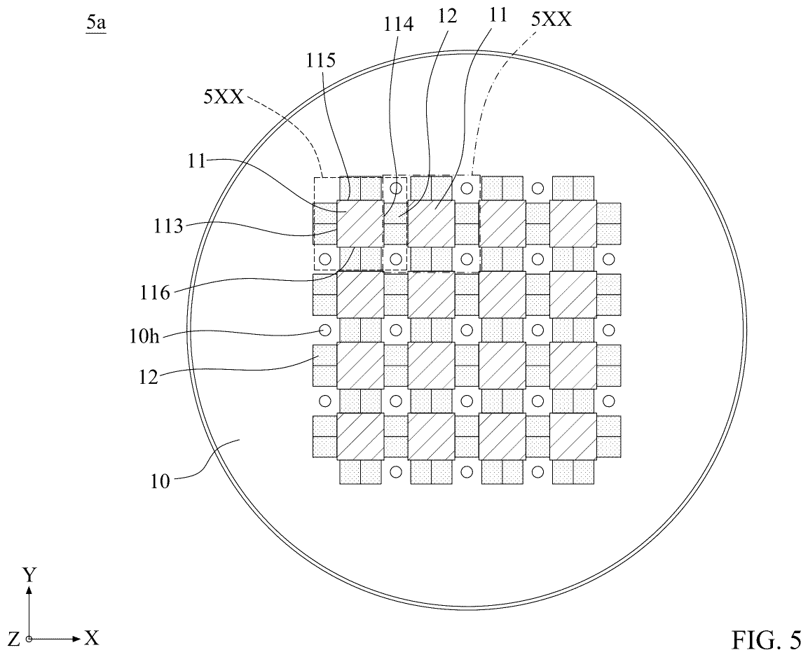

FIG. 5 illustrates a cross-sectional view of an IC structure 5a in accordance with some arrangements of the present disclosure. The IC structure 5a shown in FIG. 5 is similar to the IC structure 4a shown in FIG. 4, except for the following differences.

Referring to FIG. 5, in some arrangements, a single electronic component of the electronic components 11 and eight memories of the memories 12 may be collectively referred to as a block or a group 5XX, in which two memories 12 may be positioned along the surface 113 of electronic component 11, two along the surface 114, and two each along the surfaces 115 and 116.

The adjacent ones of the electronic components 11 may share the same memories 12. For example, two memories of the memories 12 located between two adjacent ones of the electronic components 11 along the X axis may be shared by both of these two adjacent electronic components 11. For example, two memories of the memories 12 may be shared by two adjacent groups 5XX along the X axis.

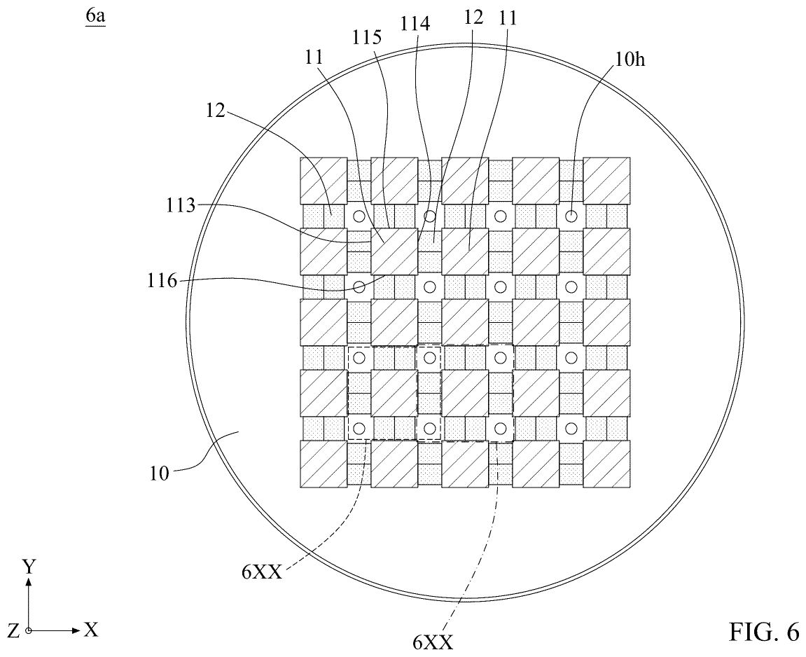

FIG. 6 illustrates a cross-sectional view of an IC structure 6a in accordance with some arrangements of the present disclosure. The IC structure 6a shown in FIG. 6 is similar to the IC structure 5a shown in FIG. 5, except for the following differences.

Referring to FIG. 6, in some arrangements, a single electronic component of the electronic components 11 and eight memories of the memories 12 may be collectively referred to as a block or a group 6XX, in which two memories 12 may be positioned along the surface 113 of electronic component 11, two along the surface 114, and two each along the surfaces 115 and 116.

Some of the outermost or peripheral ones of the electronic components 11 may communicate with or connect to fewer memories 12. For example, the electronic components 11 located at the corners of the array in the IC structure 6a can interface with four memories 12 positioned closely around them, and the electronic components 11 located along the edges of the array can interface with six memories positioned closely around them.

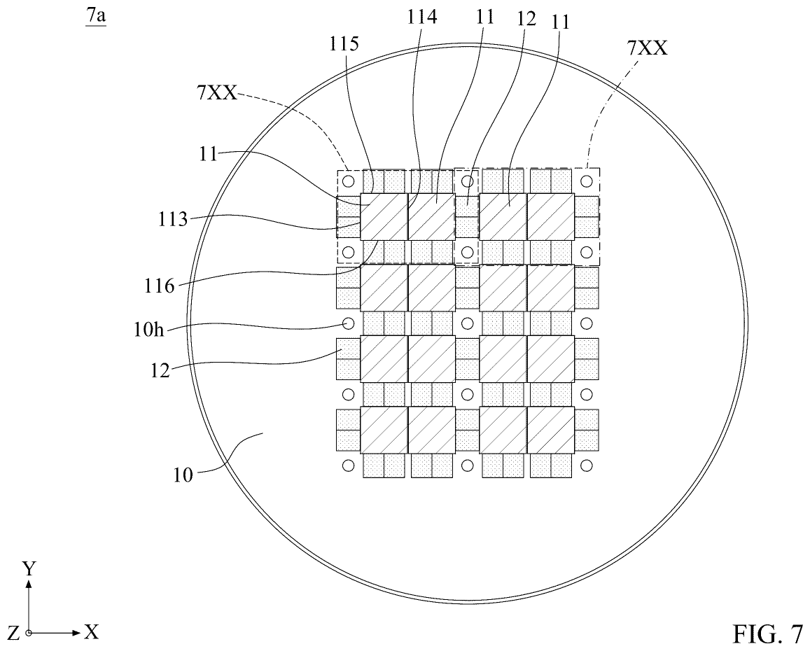

FIG. 7 illustrates a cross-sectional view of an IC structure 7a in accordance with some arrangements of the present disclosure. The IC structure 7a shown in FIG. 7 is similar to the IC structure 5a shown in FIG. 5, except for the following differences.

Referring to FIG. 7, the electronic components 11 may be arranged adjacent to one another or positioned in close proximity along the X axis, allowing for a compact and efficient spatial configuration.

For example, the electronic components 11 may be arranged in pairs. For example, the distance between two adjacent electronic components 11 along the X axis may be less than the distance between two adjacent electronic components 11 along the Y axis. In some arrangements, the electronic components 11 may be directly adjacent or near touching one another along the X axis. For example, the surface 113 of one of the electronic components 11 may be directly adjacent or near touching the surface 114 of the adjacent one of the electronic components 11.

In some arrangements, a pair of the electronic components 11 and twelve memories of the memories 12 may be collectively referred to as a block or a group 7XX, in which two memories 12 may be positioned along the surface 113 of a pair of the electronic components 11, two along the surface 114, and four each along the surfaces 115 and 116.

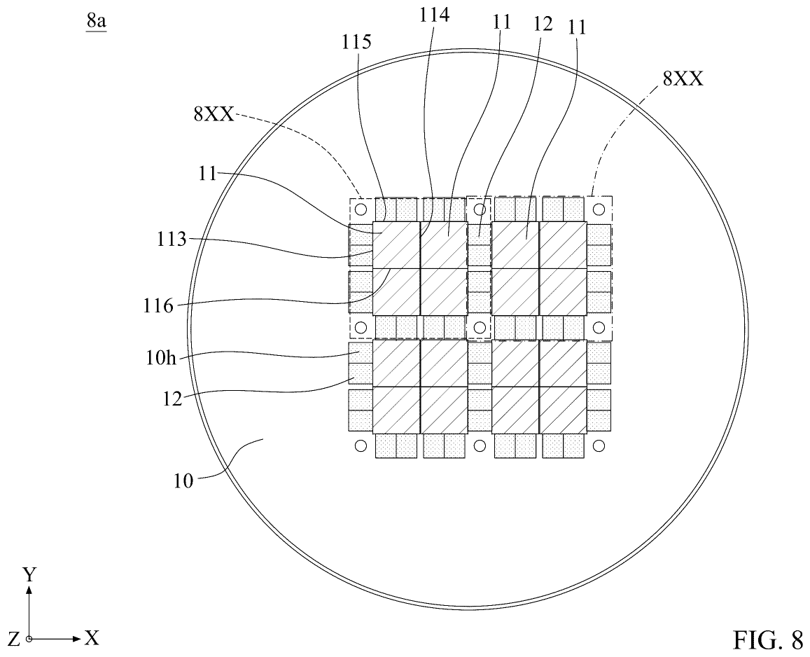

FIG. 8 illustrates a cross-sectional view of an IC structure 8a in accordance with some arrangements of the present disclosure. The IC structure 8a shown in FIG. 8 is similar to the IC structure 5a shown in FIG. 5, except for the following differences.

Referring to FIG. 8, four electronic components of the electronic components 11 may be placed so that they are either directly adjacent or nearly touching each other along both the X and Y axes. For example, four electronic components of the electronic components 11 may be disposed closer to one another than to the other electronic components 11 in the IC structure 8a.

In some arrangements, a set of the four electronic components 11 and sixteen memories of the memories 12 may be collectively referred to as a block or a group 8XX, in which four memories 12 may be positioned along the surface 113 of a set of the four electronic components 11, four along the surface 114, and four each along the surfaces 115 and 116.

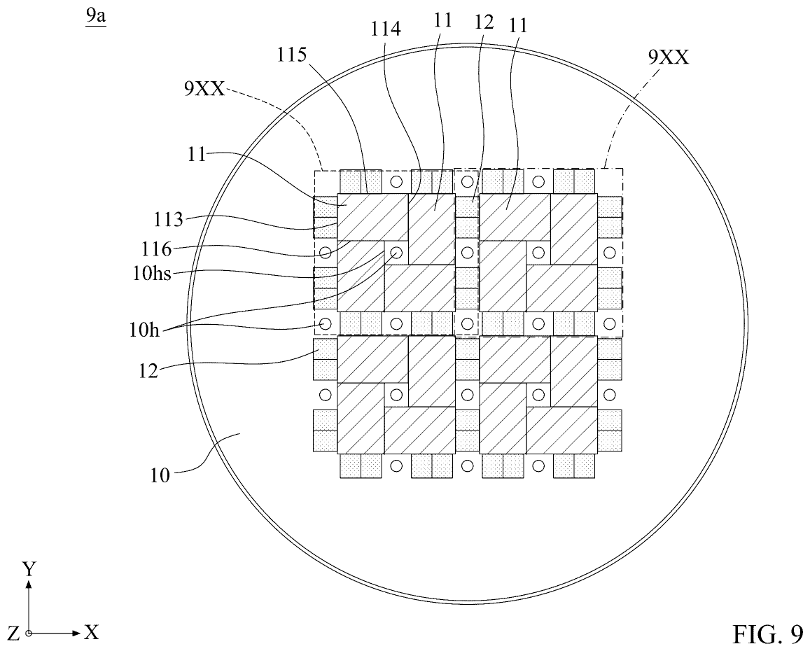

FIG. 9 illustrates a cross-sectional view of an IC structure 9a in accordance with some arrangements of the present disclosure. The IC structure 9a shown in FIG. 9 is similar to the IC structure 8a shown in FIG. 8, except for the following differences.

Referring to FIG. 9, the electronic components 11 may each have a rectangular shape. Four electronic components of the electronic components 11 may form a square pattern. A shorter side of one electronic component 11 may be aligned with a longer side of another electronic component 11.

In some arrangements, a set of the four electronic components 11 and sixteen memories of the memories 12 may be collectively referred to as a block or a group 9XX, in which four memories 12 may be positioned along the surface 113 of a set of the four electronic components 11, four along the surface 114, and four each along the surfaces 115 and 116.

In the group 9XX, four electronic components 11 may define a space 10hs (e.g., a smaller square pattern) at the center of their configuration, and one of the holes 10h may be positioned in the space 10hs. The hole 10h may be surrounded by the four electronic components 11. The four electronic components 11 may enclose the hole 10h. This arrangement allows for efficient use of space and may facilitate specific functional or structural requirements in the overall design.

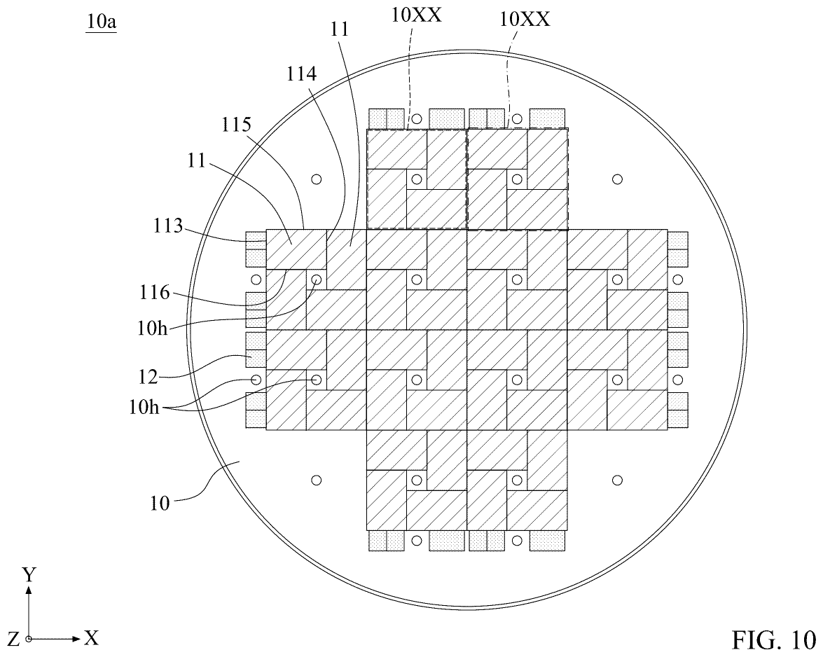

FIG. 10 illustrates a cross-sectional view of an IC structure 10a in accordance with some arrangements of the present disclosure. The IC structure 10a shown in FIG. 10 is similar to the IC structure 9a shown in FIG. 9, except for the following differences.

Referring to FIG. 10, In some arrangements, a set of the four electronic components 11 may be collectively referred to as a block or a group 10XX, in which four electronic components of the electronic components 11 may form a square pattern. A shorter side of one electronic component 11 may be aligned with a longer side of another electronic component 11.

The memories 12 may be arranged along the edges of protruding portions of the array in the IC structure 10a. The memories 12 may be disposed at the periphery of the array in the IC structure 10a. The memories 12 may not be present within the array in the IC structure 10a. The memories 12 may be positioned outside the electronic components 11. The memories 12 may be positioned peripherally relative to the electronic components 11.

In some arrangements, placing the memories 12 at the periphery of the array in the IC structure 10a may help isolate them from noisy switching activity in the core logic, thereby improving signal integrity. In addition, the memories 12 at the periphery can be designed as modular units, making it easier to scale memory size by adding or removing peripheral blocks without disturbing the core logic.

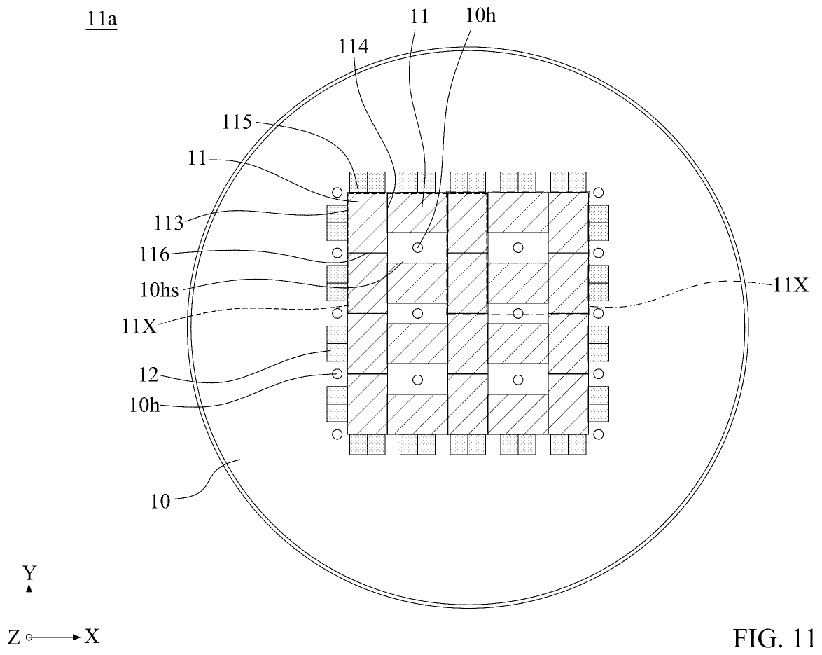

FIG. 11 illustrates a cross-sectional view of an IC structure 11a in accordance with some arrangements of the present disclosure. The IC structure 11a shown in FIG. 11 is similar to the IC structure 10a shown in FIG. 10, except for the following differences.

Referring to FIG. 11, the electronic components 11 on different columns have different orientations. For example, in a first column along the Y axis, the electronic components 11 are arranged with their longer sides aligned along the Y axis; in an adjacent second column along the Y axis, the electronic components 11 are arranged with their shorter sides aligned along the Y axis. This alternating orientation pattern enhances spatial efficiency and may contribute to improved electrical performance or thermal management within the overall IC structure.

The electronic components 11 may each have a rectangular shape. In some arrangements, a set of the six electronic components 11 may be collectively referred to as a block or a group 10XX, in which six electronic components of the electronic components 11 may form a square pattern.

In the group 10XX, six electronic components 11 may define a space 10hs (e.g., a smaller square pattern) at the center of their configuration, and one of the holes 10h may be positioned in the space 10hs. The hole 10h may be surrounded by the six electronic components 11. The six electronic components 11 may enclose the hole 10h.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and the lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amount, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An integrated circuit (IC) structure, comprising:
a carrier;
a plurality of groups arranged in an array on the carrier, each including:
an electronic component; and
a plurality of memories electrically connected with the electronic component through the carrier; and
a first hole defined by the carrier and configured to accommodate a first fixing element to hold the IC structure to another surface, wherein the hole is disposed between two rows of the array.

2. The IC structure of claim 1, wherein the carrier comprises a monolithic wafer or a monolithic panel.

3. The IC structure of claim 1, wherein in one of the groups, three memories are arranged along a first sidewall of the electronic component and other three memories are arranged along a second sidewall of the electronic component.

4. The IC structure of claim 1, wherein a distance between two adjacent electronic components along a first direction is greater than a distance between another two adjacent electronic components along a second direction.

5. The IC structure of claim 4, wherein the hole is aligned with the two adjacent electronic components along the first direction.

6. The IC structure of claim 1, wherein the plurality of memories are shared by two adjacent groups along the first direction.

7. The IC structure of claim 1, wherein the plurality of memories are shared by two adjacent groups along a first direction or a second direction substantially perpendicular to the first direction.

8. The IC structure of claim 1, wherein in a group, at least four adjacent electronic components form a square pattern.

9. The IC structure of claim 8, further comprising:
a second hole defined by the carrier and configured to accommodate a second fixing element to hold the IC structure to the another surface, wherein the second hole is surrounded by the at least four adjacent electronic components.

10. The IC structure of claim 1, further comprising:
a plurality of holes including the first hole defined by the carrier and arranged in another array.

11. An IC structure, comprising:
a carrier; and
a plurality of groups arranged in an array on the carrier, each including:
a plurality of electronic components forming a square pattern; and
a plurality of memories disposed around the plurality of electronic components and electrically connected with the carrier.

12. The IC structure of claim 11, wherein in one of the groups, the plurality of memories are disposed along four sides of the group.

13. The IC structure of claim 11, wherein one of the groups further comprises:
a hole defined by the carrier and configured to accommodate a fixing element to hold the IC structure to another surface, wherein the hole is surrounded by the plurality of electronic components.

14. The IC structure of claim 11, wherein in one of the groups, each of the plurality of electronic components has a rectangular shape, and a shorter side of one of the plurality of electronic components is aligned with a longer side of another one of the plurality of electronic components.

15. An IC structure, comprising:
a wafer having a first surface;
a first electronic component disposed over the first surface of the wafer;
a second electronic component disposed over the first surface of the wafer and aligning with the first electronic component along a first direction; and
a plurality of memories disposed over the first surface of the wafer, and disposed between the first electronic component and the second electronic component along the first direction,
wherein the plurality of memories are electrically connected to the first electronic component and the second electronic component through the wafer,
wherein the plurality of memories are aligned with one another along a second direction.

16. The IC structure of claim 15, further comprising:
an encapsulant covering the first electronic component, the second electronic component, and the plurality of memories, wherein the encapsulant separates the plurality of memories from the first electronic component and the second electronic component.

17. The IC structure of claim 16, further comprising:
a connector disposed over the first surface of the wafer and partially covered by the encapsulant.

18. The IC structure of claim 17, further comprising:
a voltage regulator disposed over a second surface of the wafer opposite to the first surface.

19. The IC structure of claim 16, further comprising:
a connector disposed over a second surface of the wafer opposite to the first surface.

20. The IC structure of claim 16, wherein the plurality of memories are electrically connected with the first electronic component through an interposer embedded in the wafer.
